(19) United States
(12) Patent Application Publication
(10) Pub. No.: US 2007/0222474 A1
(43) Pub. Date: Sep. 27, 2007

(54) Device for Detecting a Fixed Image on a Liquid Crystal Display Screen

(76) Inventor: Frederic de Lauzun, Saint Medard En Jalles (FR)

Correspondence Address: LOWE HAUPTMAN & BERNER, LLP, 1700 DIAGONAL ROAD, SUITE 300, ALEXANDRIA, VA, 22314, US

(21) Appl. No.: 10/593,408

(22) PCT Filed: Mar. 16, 2005
(86) PCT No.: PCT/EP05/51209

§ 371 Date: Sep. 19, 2006

(30) Foreign Application Priority Data
Mar. 19, 2004 (FR) 04 02871

(51) Int. Cl. G01R 31/00

(52) U.S. Cl. 324/770

(57) ABSTRACT

A device for detecting a frozen image on a liquid crystal display screen comprises at least one photoelectric cell capable of delivering a luminance signal l(t) to means (8) for processing this signal. The cell is placed facing a display area (A) of the screen. In this display area, a variable pattern is displayed at a characteristic frequency f_{c}. The processing means are capable of detecting the characteristic frequency in the signal l(t). If this signal is not detected, they trigger a corresponding alarm.

### TECHNICAL FIELD

The invention relates to a device for detecting a frozen image on a liquid crystal display screen. The invention applies more particularly to liquid crystal display screens of the transmissive type, like those used on vehicle instrument panels, in particular for aircraft.

### STATE OF THE ART

In the current state of the art of head-down display systems for aircraft, it is common to use, as display, a flat color liquid crystal display screen controlled by an active matrix. These are called AMLCD (Active Matrix Liquid Crystal Display) screens.

These flat color LCD screens are universally used for all airplane and helicopter cockpit displays. They provide, by the parameters displayed, the main man/machine interface for pilots.

A liquid crystal screen essentially comprises a matrix of electrooptic cells arranged in rows and columns, each driven by a switching device (for example a TFT transistor). Each cell comprises a pixel electrode and a counterelectrode flanking a liquid crystal, the optical properties of which are modified according to the field across it.

The combination formed from a switching device and an electrooptic cell constitute what is called a picture element or pixel.

These pixels are addressed via row select lines (or gate lines), which control the conducting or nonconducting state of the switching devices, and via column select lines (or data lines), which transmit a voltage, corresponding to a data signal to be displayed, namely a gray level, to each pixel electrode when the associated switching device is in the on state.

More precisely, the circuits for addressing such a matrix comprise gate-line or gate drivers and data drivers. These drivers may be circuits integrated into the active matrix (that is to say they are produced on the same substrate board as the active matrix) or they may be external circuits. In the latter case, they are connected to the active matrix via a connector, for example of the anisotropic conductive film type.

The gate driver comprises mainly one or more shift registers for addressing, sequentially, each of the gate lines of the matrix at a vertical scan frequency.

The data driver mainly comprises one or more shift registers, receiving, as input for each gate line of the matrix, the data to be displayed. This data indicates the gray level to be applied for each column of the matrix. Typically, for each column, this gray level is coded over 6 or 8 bits.

For each new line, the data preloaded in the register is transferred as output, to be applied to the input of a digital/analog converter. This converter delivers, as output, a corresponding analog voltage level, in order to display the desired gray level on each of the pixels of the selected line.

The addressing circuit generally includes other control devices, especially for reversing the polarity of the voltage applied to the pixels and to take into account the structure (quad, strip, etc.) of the color filter of the matrix. These address circuits are well known to those skilled in the art.

In the field of avionics, such screens are used in particular in head-down display systems. They constitute an essential man/machine interface, providing the pilot, by means of sophisticated symbolic images, information needed for him to carry out his various missions correctly.

The information displayed must be reliable. The integrity of the information chain comprises the integrity of the sensors, the integrity of the information sources and the integrity of the display system. In particular, the display system must be designed with integrated control circuits capable of detecting a malfunction and of alerting the pilot in the event of a malfunction. This may for example be accomplished by means of a warning lamp, or an alarm display console indicating the nature of the malfunction detected in the display system.

Avionic displays must also respond to very strict visual criteria (resolution, luminance, viewing angle, etc.) and currently have specific aspect ratios, different from the computer and multimedia aspect ratios.

Display screens specifically designed for avionic applications are thus very expensive, and the number of suppliers is limited.

For these various reasons, there is a trend toward standardizing the aspect ratios, for the purpose of making the production of these screens more profitable, by reducing costs.

One feature of this trend is the use of what are called COTS (Component On The Shelf) screens with aspect ratios conforming to the computer standard.

Such COTS screens generally have very good performance, especially optical performance, but they do not incorporate the security aspects needed in avionics.

In particular, it has been observed that such a screen could display a fault of the frozen image type, generally corresponding to an operating fault in the shift registers of the row or column drivers.

More precisely, an n-bit shift register is a semiconductor device comprising n stages in cascade, each stage comprising a plurality of semiconductor transistors. These transistors must perform numerous switching operations. Some of these transistors suffer permanently from gate stress, which may cause a drift in their threshold voltage and consequently a malfunction of the transistor—the transistor no longer switches. In a switching stage in which a transistor no longer switches, data can no longer be transferred—the data output by this stage and the following stages therefore can no longer change. With regard to the shift registers of the row select driver, the rows controlled by the output of these stages will therefore always remain in the same unselected state—the rows can no longer be scanned. With regard to the shift registers of the column driver, the pixel elements of the columns controlled by the output of these stages will therefore always remain in the same state.

Thus, the use of commercial display screens may lead to a frozen image fault in operation.

The pilot may take some time before noticing such a fault, the more so as certain symbolic images associated with information useful for the pilot do not vary very quickly. Not to detect such a fault is dangerous from the standpoint of operational safety. It is therefore necessary to provide a system for detecting such a fault.

### SUMMARY OF THE INVENTION

The object of the invention is to propose such a system.

Thus, the invention relates to a device for detecting a frozen image on an active-matrix liquid crystal screen, comprising :
a photoelectric cell covering a display area of said screen, said cell being capable of delivering an electrical signal representative of luminance in said area;
control means for displaying a variable pattern at a characteristic frequency in said display area;
means for processing an electrical signal delivered by said cell, in order to detect said frequency; and
means for displaying an alarm should said frequency not be detected.

The variable pattern preferably corresponds to an on/off control for the pixel elements in this area at said characteristic frequency.

Advantageously, the characteristic frequency can be varied.

The matrix being arranged in rows and columns and driven by a row select driver and a data display or column driver, and the drivers comprising shift registers with a plurality of cascaded stages, the display area preferably corresponds to the rows and columns of the matrix controlled by the last stages of said shift registers.

According to a first variant of the invention, a light-emitting diode is provided as back light source for said display area.

According to another variant of the invention, the detection device includes first and second cells placed side by side facing said display area, one operating in low-luminance mode and the other operating in high-luminance mode.

### BRIEF DESCRIPTION OF THE DRAWINGS

Still other objects and advantages of the present invention will become readily apparent to those skilled in the art from the following detailed description, wherein the preferred embodiments of the invention are shown and described, simply by way of illustration of the best mode contemplated of carrying out the invention. As will be realized, the invention is capable of other and different embodiments, and its several details are capable of modifications in various obvious aspects, all without departing from the invention.

Accordingly, the drawings and description thereof are to be regarded as illustrative in nature, and not as restrictive.

FIG. 1 is a block diagram of an active-matrix liquid crystal display screen used in a display system;

FIG. 2 is a block diagram of the row and column drivers of an active matrix;

FIG. 3 is a block diagram of a first embodiment of a detection device according to the invention;

FIG. 4 is a schematic sectional view of a screen provided with a cell according to one embodiment of the invention;

FIG. 5 is a block diagram showing another embodiment of a detection device according to the invention; and

FIGS. 6a and 6b show flow diagrams for a detection circuit according to the invention.

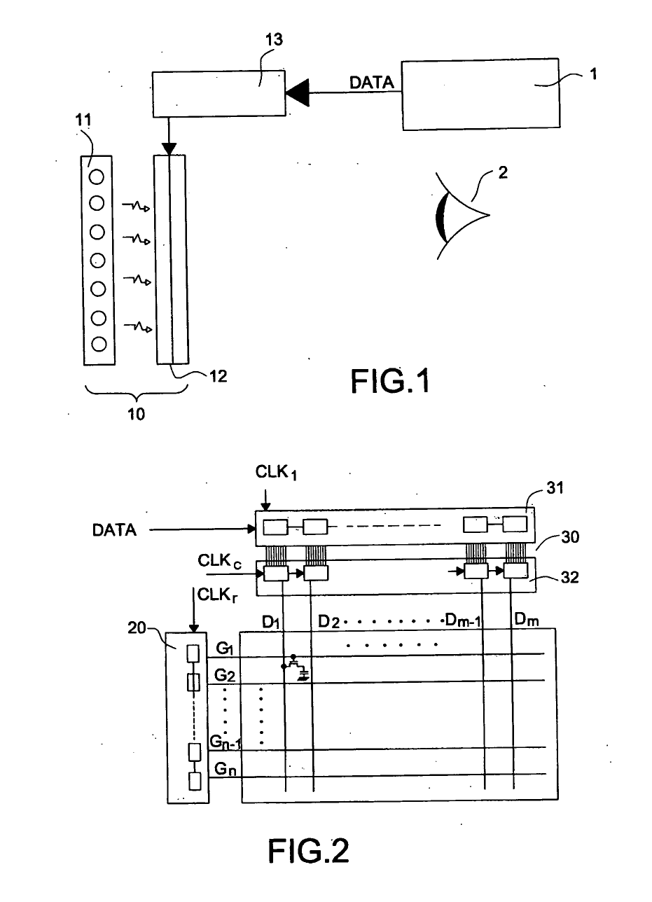

### DETAILED DESCRIPTION OF THE INVENTION

An active-matrix liquid crystal display screen 10 usually comprises a backlight source 11, which illuminates the back face of the active matrix 12, which comprises simplistically two glass plates between which the liquid crystal lies. The screen is placed so that the image displayed on the front face of the screen is seen by an operator 2. This active matrix is controlled by a circuit 13, which may or may not be integrated into the matrix and which receives the data DATA, corresponding to an image to be displayed, from a computer 1 of a display system. Typically, when displaying symbolic images in an aircraft, this data is in practice delivered by one or more graphics processors on the basis of measurement signals from various sensors. The function of these graphics processors is to periodically generate a complete matrix image to be displayed on the screen. This complete image is in practice stored in an image memory that comprises at least as many binary words as there are pixels in the matrix, each binary word representing the luminance or gray level of the pixel associated with this word.

FIG. 2 shows simplistically a circuit for controlling the display of an image on the matrix. This circuit comprises a row select driver 20 for the rows G₁, G₂, . . . Gₙ and a column driver 30 for the columns D1, D2, . . . Dₘ.

The function of the row select driver is to sequentially select each of the rows of the matrix at the frequency of a row clock CLKᵣ. Typically, this is obtained by a shift register that is incremented at each clock pulse CLKᵣ.

The function of the column driver is to select the voltage level to be applied to each column of the matrix, depending on the binary word that codes the gray level information for this column. For example, the gray level is coded over 8 bits. The data stream DATA received as input from the driver is thus a sequence of words (bytes), each word coding the gray level to be displayed on the pixel corresponding to a column or to the row selected. This data is input in sequence into a shift register 31 at the frequency of a column clock CLK_{c}. At each row clock pulse, this data is transferred into shift registers of a conversion circuit 32, which makes it possible to apply, to each column, a voltage level corresponding to the stored gray level. The polarity of this voltage may also be reversed, in a known manner, depending on the address mode of the matrix (addressing in row inversion mode, point inversion mode, etc.) in order to improve the visual quality of the images displayed. These various aspects are well known to those skilled in the art and will not be detailed here.

Shift registers are usually formed from transistors. As has been seen, these transistors may, under the repeated effect of the voltages applied to them, become defective. Data is no longer transferred between the defective stage and the next stage in cascade. The data output by the detective stage and the data output by the following stages no longer changes.

In particular in the case of the row select driver, the last rows are no longer selected—they will therefore always keep the same information on their pixel elements, at least as long as the pixel capacitor remains charged.

In the case of the column driver, the pixel elements on the last columns always retain the same information.

Whatever the rank of the defective stage in the register, this frozen image fault will always be observed on at least the last rows and last columns corresponding to the last stages of the registers, that is to say quite universally, in the bottom right corner of the screen.

According to the invention, by placing a photoelectric cell in this area of the screen and by displaying, in this area, a pattern that varies over time, at least at a characteristic frequency, it may be verified that this characteristic frequency is indeed in the resulting brightness signal. If this frequency is not found, it may be deduced therefrom that a frozen image fault is present, and an alarm is triggered (for example, a malfunction message is displayed or a warning lamp turned on).

The dimensions of the test area according to the invention are in practice small. For example, with a screen designed with a 200 micron pitch, an area of the screen defined by the last five columns and the last five rows, i.e. a few square millimeters in size, will be used.

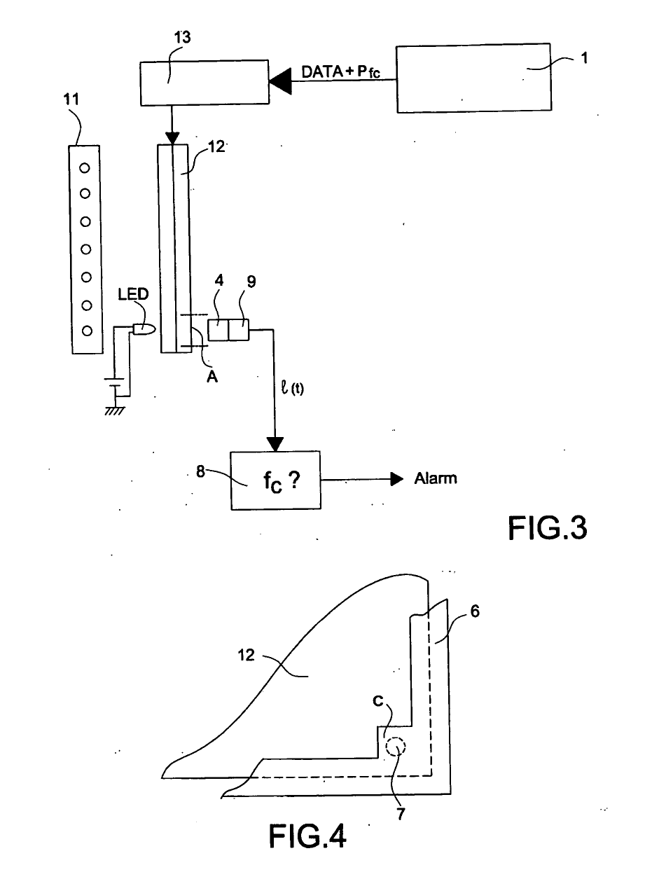

A device for detecting a frozen image defect according to the invention is shown schematically in FIG. 3.

An LCD screen is shown in cross section. The light transmitted by a display area A located at the bottom of the screen is detected by a photoelectric cell 4 appropriately collimated on this area.

This photoelectric cell 4 and the area A are protected from the ambient light by an optical mask 5. In the example shown in cross section in FIG. 4, this optical mask is produced by the bezel 6 of the screen, the shape of which is designed to cover the display area A and to incorporate the cell 4 in a cavity 7 provided in the bezel 6 for this purpose. The shape of the bezel is thus in the form of a corner piece C (FIG. 4).

The electrical signal l(t) delivered by the photoelectric cell 4 is applied as input to an electronic card 8 for processing this signal.

A test pattern is displayed in the display area A. In practice, the corners of the screen are little used or not at all by the display system. The operational image (symbolic image) displayed is therefore not degraded.

The time (or frequency) variation of the test pattern is obtained in practice simply by an on/off control of the pixel elements in this area, at a characteristic frequency f_{c}. In other words, alternately imposed on the pixel elements in this area A, at the characteristic frequency f_{c}, are a voltage corresponding to the maximum gray level (on state) and then a voltage corresponding to the minimum gray level (off state), and so on.

The electrical signal l(t) must therefore, in normal operation, have the characteristic frequency f_{c}, due to the alternating sequence of luminance values representative of the on and off states of the pixel elements. It is this that the electronic card 8 detects.

In practice, the frequency be may detected by any circuitry known to those skilled in the art.

In one example, an analog/digital conversion circuit is provided for sampling the signal l(t) at a suitable sampling frequency, together with a comparator for comparing the sampled value with a previously sampled and stored value. In practice, the characteristic frequency f_{c} is equal to k times the sampling frequency (k>1) so as for there to be sufficient integration of the luminance signal, compared with the image scan frequency. If, at the frequency f_{c}, the samples have a different value, the screen is considered to be operating correctly. If at the frequency f_{c} the samples have the same value, it is considered that there is a frozen image defect. In practice, provision may be made for this defect to be verified two more times before the corresponding alarm is triggered (to prevent false alarms).

In another example, this frequency detection is performed by comparison means of the analog type. In this case, the charging and discharging of a capacitor by the signal l(t) is typically used. As soon as the signal l(t) becomes constant, due to a frozen image defect, charging or discharging no longer takes place, and it is this that is detected.

According to one practical implementation of a detection device according to the invention, it is necessary to take into account the warm-up time of the screen, each time it is turned on. This is because, as is well known, until the screen is at a sufficient temperature its transmission properties are highly degraded. It is therefore necessary to inhibit the detection device during this warm-up period. This may be accomplished by introducing a delay, which allows the device to be activated only when a certain time has elapsed after turning the display on. However, since the warm-up time will vary depending on the operational and environmental conditions, it is preferable to provide an activation signal delivered by a device for measuring the minimum ambient temperature. Another way of solving this problem is to display a specific pattern in the test area, which delivers a test start signal to the detection device as soon as the processing card detects it. This start signal triggers the device for controlling the display of the on/off test pattern at the characteristic frequency f_{c}. The specific start pulse pattern may for example be a predetermined specific gray level.

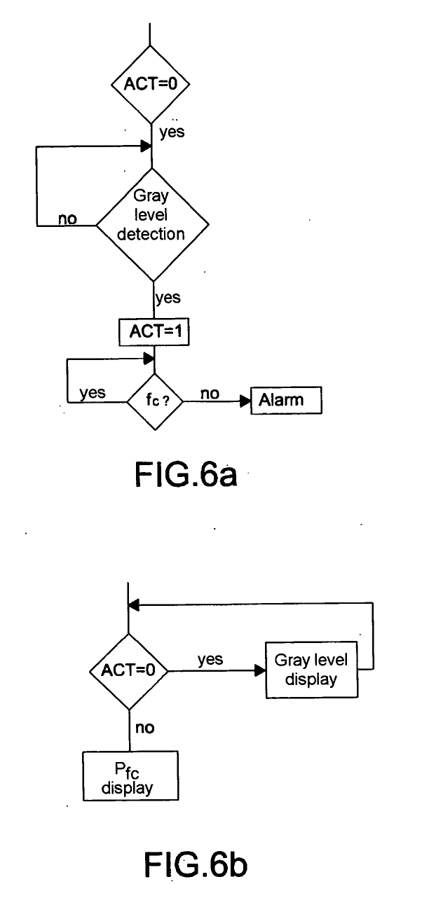

An operational flow chart corresponding to a detection device according to the invention is shown in FIG. 6a relating to detection performed by the electronic card 8 and in FIG. 6b relating to the control of the display in the test area A. A binary indicator ACT is provided, set (typically to zero) each time the display is turned on.

While it is at zero, the device causes the predetermined specific gray level to be displayed in the test area A, and the processing card is configured for detecting this specific gray level.

As soon as this gray level is detected, the binary indicator ACT is set to one. The device causes the on/off test pattern to be displayed in the test area A and the processing card is configured to detect the characteristic frequency f_{c}.

The characteristic frequency f_{c} is chosen in practice according to the modulation frequency of the light source, generally around 300 hertz, and to the line scan frequency of the screen (50 or 60 hertz) . It must also be chosen so as to allow reactive and sufficiently rapid detection of a failure (frozen image fault).

In practice, f_{c} will be chosen within the 1 to 10 hertz range.

According to another implementation aspect of the invention, it is necessary to take into account the variation in luminance of the backlight source of the screen. This is because, in particular in the avionics field, it is necessary to slave the luminance of the back light source of the screen to the ambient brightness, so that the symbolic images displayed are always correctly perceived by the observer (the pilot). In a known exemplary embodiment, the back light source is formed by a set of fluorescent lamps pulse-controlled in PWM mode so that the variation in luminance is controlled by the modulated duration of the pulses.

The luminance obtained on the front face of the screen is the product of the luminance delivered by the light source and the transmission factor of the multilayer stack between this light source and the front face of the screen. This transmission factor may be around 4% to 8% for a screen having a CR of 50/1. It will vary from one screen to another and with the ambient temperature.

In one example, in daylight (high luminance), the luminance level corresponding to the off state will be around 7 candelas per m² and the luminance level corresponding to the on state will be around 350 candelas per m².

At night time (low luminance), the luminance level corresponding to the off state will be around 0.003 candelas per m² and the luminance level corresponding to the on state will be around 0.16 candelas per m².

The photoelectric cell 4 must therefore be chosen to have a high sensitivity corresponding to the dynamic range of the screen output luminance—it must be able to discern between 7 and 350 cd/m² in conditions of high ambient luminance and between 0.003 and 0.16 cd/m² in conditions of low ambient luminance. It must also have a large output range in order to detect the rising or falling edges corresponding to the variations in luminance detected by both high ambient luminance levels and low ambient luminance levels.

In practice, it is also preferable to provide an amplifier 9, typically an operational amplifier, in order to amplify the signal and minimize the noise level. Preferably, this amplifier 9 will be placed in the immediate vicinity of the photoelectric cell 4 so as to reduce the electromagnetic interference effects. Preferably, the photoelectric cell 4 and its signal amplifier 9 will be housed in the cavity 7 provided in the corner area C of the bezel 6 of the screen. The bezel, or at least the corner area containing the cell, and preferably containing the cell and the amplifier, is of the type protected against electromagnetic interference (typically made of metal, and connected to ground).

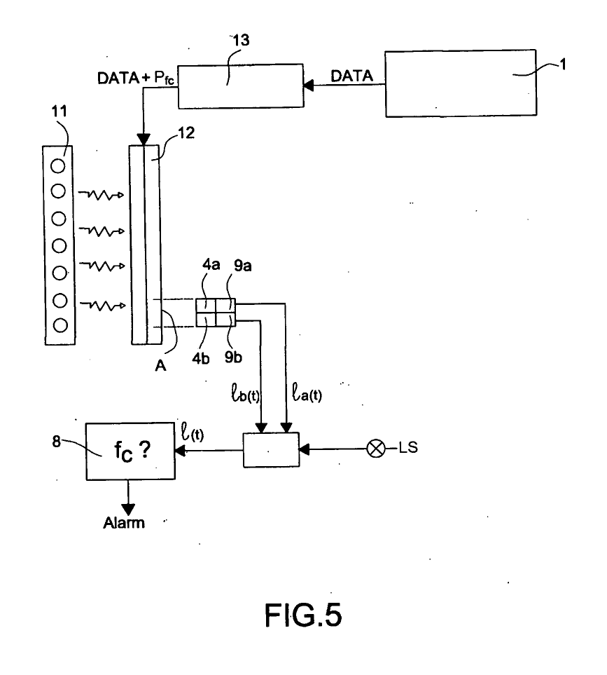

In a first embodiment shown in FIG. 5, two photoelectric cells 4a and 4b may be provided, placed side by side facing the display area A, a first cell 4a being designed for optimum sensitivity and optimum output dynamic range under low ambient luminance conditions and a second cell being designed for optimum sensitivity and optimum output dynamic range under high ambient luminance conditions. Each cell outputs a luminance signal, la(t) and lb(t) respectively. Preferably, a signal amplifier, 9a, 9b respectively, is provided, advantageously placed close to the associated cell, in order to amplify the signal and minimize the noise, as will be seen in the next paragraph. The processing of one or other luminance signal (possibly amplified) in the processing card 8 is controlled by an ambient luminance sensor LS. Thus, depending on the ambient luminance, one or other cell is used operationally. The two cells 4a, 4b are housed, preferably with their associated signal amplifier 9a, 9b, in the cavity 7 provided in the bezel 6 of the screen, in the corner area C that overlaps the test area A (FIG. 4). The bezel 6, or at least the corner area, is of the type protected against electromagnetic interference.

In another embodiment of the invention, shown in FIG. 3, this problem of variation in luminance of the back light source is overcome by providing a specific light source for the test area A. In practice, this specific light source is an LED (light-emitting diode). This is because light-emitting diodes are capable of operating satisfactorily irrespective of the ambient temperature.

In practice, this light-emitting diode is placed between the main back light source and the rear layer of the multilayer stack of the screen, typically the diffusion plate, designed to make the light uniform. This diode is provided with an associated collimation device, defined so as to optimize said display area A.

A detection device according to the invention thus serves to detect a frozen image fault on a liquid crystal display.

It allows commercial display screens to be used in applications in which the level of integrity of the data displayed is very important, typically in the avionics field.

The invention is not limited to this field. In particular, it relates equally well to display screens of the transmissive or transflexive type, which are used for displaying symbology images or video images.

The invention is not limited to the embodiments described by way of implementation example. In particular, more sophisticated test patterns P_{fc} may be used, for example patterns that depend on the temperature. One or more characteristic frequencies may be provided in the test pattern, in order to overcome parasitic effects (PWM control frequency of the light box). It is also possible to provide a characteristic frequency that can be varied. These various alternatives make it possible to provide richer information display, allowing the integrity of the detection chain to be verified, for example by means of a check sum control on the image displayed in the test area.

Provision may be made for the detection according to the invention to take place in only one test area, preferably in the bottom right corner, allowing faults due to the row driver and column driver to be detected. However, other arrangements may be provided.

The variable test pattern P_{fc} to be displayed in the display area A may be generated by a specific electronic circuit associated with the screen, which may be integrated into the circuit 13 that receives the data DATA to be displayed, as shown schematically in FIG. 5. It may also be generated by the graphics processor or processors (1) that control the images to be displayed on said screen, as shown schematically in FIG. 3.

It will be readily seen by one of ordinary skill in the art that the present invention fulfills all of the objects set forth above. After reading the foregoing specification, one of ordinary skill in the art will be able to affect various changes, substitutions of equivalents and various aspects of the invention as broadly disclosed herein. It is therefore intended that the protection granted hereon be limited only by the definition contained in the appended claims and equivalent thereof.

1-12. (canceled)

13. A device for detecting a frozen image on an active-matrix liquid crystal display screen, comprising:
a photoelectric cell covering a display area of said screen, said cell being capable of delivering an electrical signal representative of luminance in said area;
control means for displaying a variable pattern at a characteristic frequency in said display area;
means for processing an electrical signal delivered by said cell, in order to detect said frequency; and
means for displaying an alarm should said frequency not be detected.

14. The detection device as claimed in claim 13, wherein said variable pattern corresponds to an on/off control for the pixel elements in said display area at said characteristic frequency (f_{c}).

15. The detection device as claimed in claim 13, wherein the characteristic frequency can be varied.

16. The detection device as claimed in claim 13, wherein the matrix is arranged in rows and columns and is driven by a row select driver and a data display or column driver, and the drivers comprises shift registers with a plurality of cascaded stages, wherein the display area corresponds to the rows and columns of the matrix controlled by the last stages of said shift registers.

17. The detection device as claimed in claim 13, comprising a light-emitting diode as back light source for said display area.

18. The detection device as claimed in claim 13, including first and second cells placed side by side facing said display area, one cell operating in low-luminance mode and the other cell operating in high-luminance mode.

19. The detection device as claimed in claim 13, wherein the cell or cells are housed in a cavity provided in a corner area of a frame for said screen, said corner area overlapping the display area.

20. The detection device as claimed in claim 19, wherein the frame or at least said corner area of the frame is of the type protected from electromagnetic interference.

21. The detection device as claimed in claim 13, wherein said means for processing the electrical signal delivered by the cell(s) comprise an amplifier element, for amplifying said signal, which is placed as close as possible to the cell(s).

22. The detection device as claimed in claim 21, wherein said amplifier element is placed in the cavity in the immediate vicinity of an associated cell.

23. The detection device as claimed in claim 13, wherein the variable pattern to be displayed in said display area is generated by a specific electronic circuit associated with the screen.

24. The detection device as claimed in claim 1, wherein the variable pattern to be displayed in said display area is generated by one or more graphics processors that control the images to be displayed on said screen.

25. The detection device according to claim 18, wherein the cell or cells are housed in a cavity provided in a corner area of a frame for said screen, said corner area overlapping the display area.

26. The detection device as claimed in claim 21, wherein said amplifier element is placed in the cavity in the immediate vicinity of an associated cell.

27. The detection device as claimed in claim 26, wherein said amplifier element is placed in the cavity in the immediate vicinity of an associated cell.
